(19) United States
(12) Patent Application Publication
(10) Pub. No.: US 2013/0153286 A1
(43) Pub. Date: Jun. 20, 2013

(54) SHIELDING SYSTEM FOR MOBILE DEVICE AND METHOD FOR ASSEMBLING THE SYSTEM

(71) Applicant: Samsung Electronics Co., Ltd., Suwon-si (KR)

(72) Inventors: Jeongung KIM, Suwon-si (KR); Jaewoo JEONG, Seoul (KR); Kuntak KIM, Suwon-si (KR); Hyunjoo HAN, Yongin-si (KR); Seyoung JANG, Seongnam-si (KR)

(73) Assignee: Samsung Electronics Co., Ltd., Suwon-si (KR)

(21) Appl. No.: 13/710,956

(22) Filed: Dec. 11, 2012

(30) Foreign Application Priority Data
Dec. 16, 2011 (KR) 10-2011-0136348

(51) Int. Cl. H05K 9/00; H05K 3/00

(52) U.S. Cl. CPC H05K 9/0007; H05K 3/00
USPC 174/377; 29/829

(57) ABSTRACT

A shielding system for a mobile device and a method for assembling the system are provided. The shielding system includes a Printed Circuit Board (PCB) with a first area and a thickness, and a shield enclosure, spaced apart and above a front side of the PCB at a certain distance, for enclosing components on the PCB. Parts of the shield enclosure are coupled to at least one of a lateral side and a back side of the PCB.

### PRIORITY

This application claims the benefit under 35 U.S.C. §119(a) of a Korean patent application filed on Dec. 16, 2011 in the Korean Intellectual Property Office and assigned Serial No. 10-2011-0136348, the entire disclosure of which is hereby incorporated by reference.

### BACKGROUND OF THE INVENTION

1. Field of the Invention

The present invention relates to a shielding system for a mobile device. More particularly, the present invention relates to a shielding system that can be easily installed on a Printed Circuit Board (PCB) of a mobile device for increasing the stiffness, without causing a pressure applied thereto, and a method for assembling the shielding system.

2. Description of the Related Art

As technology for mobile devices continues to be developed, the number of users of such mobile devices continues to increase. That is, because mobile devices provide a mobile communication function, as well as various additional functions based on the convergence of technologies, mobile devices are commonly used. Moreover, mobile devices continue to be developed to provide a variety of advanced functions to meet users' needs. To this end, they are equipped with a variety of hardware components.

Mobile devices of the related art integrate hardware components onto a PCB. For example, a mobile device integrates a communication chip for supporting a mobile communication function and a process chip for supporting a multimedia function onto one PCB. The PCB may also include a processing chip for supporting a touch screen function, and various modules for supporting a number of user functions, such as a broadcast receiving module, a short-range communication module, etc. However, when the hardware components perform switching operations to process data, they cause noise. Such noise affects the nearby processing chips. In order to address the noise that occurs when the chips operate, such as while they support a communication function, the PCB of the related art is partially covered with a conductive shield enclosure. Such a conductive shield enclosure is intended to prevent the propagation of noise and to provide stiffness to the PCB.

Shield enclosures of the related art are fixed onto PCBs via mechanical members, such as screws. To this end, a PCB includes coupling areas that allows the PCB to be coupled with the shield enclosure by a mechanical means such as a screw. The shield enclosure is placed on the PCB and then fixed thereon as screws are coupled to the coupling areas. However, since there is a constant demand for mobile devices to be thinner and to be equipped with additional hardware components, it is difficult to maintain sufficient space in design or technique. In addition, shield enclosures of the related art that are fixed to PCBs via a screw coupling system are disadvantages in that they come off the PCBs, provide only a small number of coupling space areas due to the volume limitation of mobile devices, and thus cannot provide a sufficient level of stiffness to adequately support the mobile device.

Accordingly, there is a need for an improved shielding system that is easily installed on a PCB of a mobile device and that can secure space and increase stiffness of the mobile device.

### SUMMARY OF THE INVENTION

Aspects of the present invention are to address at least the above-mentioned problems, and/or disadvantages and to provide at least the advantages described below. Accordingly, an aspect of the present invention is to provide a shielding system, including a shielding enclosure that is easily installed on a Printed Circuit Board (PCB) of a mobile device, that can secure space and increase stiffness.

Another aspect of the present invention is to provide a method for assembling a shielding system.

In accordance with an aspect of the present invention, a method for assembling a shielding system is provided. The method includes providing a PCB, providing a shield enclosure that comprises a cover, above the PCB, and a fixing lead extending from the cover, and fixing the fixing lead of the shield enclosure to at least one of a lateral side and a back side of the PCB.

In accordance with another aspect of the present invention, a shielding system for a mobile device is provided. The system includes a PCB with a first area and a thickness and a shield enclosure, spaced apart and above a front side of the PCB at a certain distance, for enclosing components on the PCB, wherein parts of the shield enclosure are coupled to at least one of a lateral side and a back side of the PCB.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features, and advantages of certain exemplary embodiments of the present invention will be more apparent from the following description viewed in conjunction with the accompanying drawings, in which:

FIG. 1 illustrates a perspective view showing a shielding system according to a first exemplary embodiment of the present invention;

FIG. 2 illustrates a perspective view showing a shield enclosure of the shielding system shown in FIG. 1 according to an exemplary embodiment of the present invention;

FIG. 3 illustrates a perspective view showing the Printed Circuit Board (PCB) shown in FIG. 1 according to an exemplary embodiment of the present invention;

FIG. 4 illustrates a side view showing the shield enclosure shown in FIG. 1 along a lengthwise direction according to an exemplary embodiment of the present invention;

FIG. 5 illustrates a side view showing the shield enclosure shown in FIG. 1 along a widthwise direction according to an exemplary embodiment of the present invention;

FIG. 6 illustrates a top view showing the shield enclosure shown in FIG. 1 according to an exemplary embodiment of the present invention;

FIG. 7 illustrates a perspective view showing a shielding system according to a second exemplary embodiment of the present invention;

FIG. 8 illustrates a perspective view showing a shield enclosure of the shielding system shown in FIG. 7 according to an exemplary embodiment of the present invention;

FIG. 9 illustrates a perspective view showing a PCB shown in FIG. 7 according to an exemplary embodiment of the present invention;

FIG. 10 illustrates a side view showing the shield enclosure shown in FIG. 7 along a lengthwise direction according to an exemplary embodiment of the present invention;

FIG. 11 illustrates a side view showing the shield enclosure shown in FIG. 7 along a widthwise direction according to an exemplary embodiment of the present invention;

FIG. 12 illustrates a perspective view showing a shielding system according to a third exemplary embodiment of the present invention;

FIG. 13 illustrates a perspective view showing a shielding system according to a fourth exemplary embodiment of the present invention;

FIG. 14 illustrates a perspective view showing a modification of the shielding system shown in FIG. 13 according to an exemplary embodiment of the present invention;

FIG. 15 illustrates a perspective view showing a shielding system according to a fifth exemplary embodiment of the present invention; and

FIG. 16 illustrates a flowchart that describes a method for assembling a shielding system according to an exemplary embodiment of the present invention.

Throughout the drawings, it should be noted that like reference numbers are used to depict the same or similar elements, features, and structures

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

Detailed descriptions of well-known functions and structures incorporated herein may be omitted to avoid obscuring the subject matter of the invention.

Although the drawings represent exemplary embodiments of the present invention, the drawings are not necessarily to scale and certain features may be exaggerated or omitted in order to better illustrate and explain the invention.

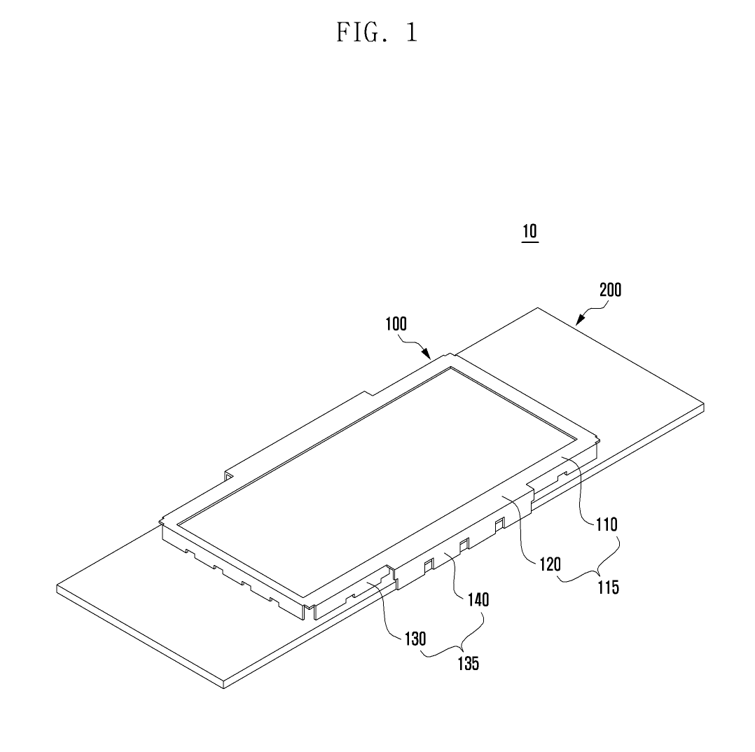

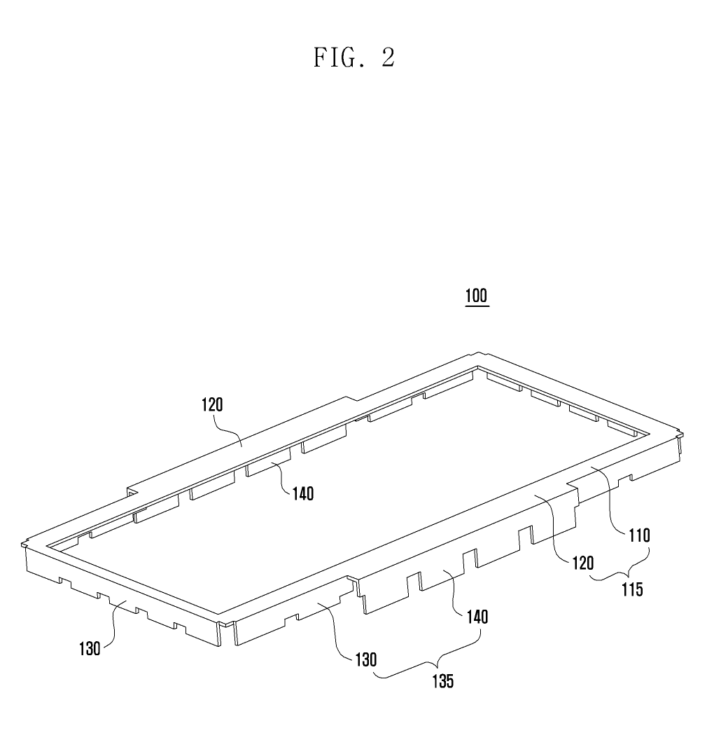

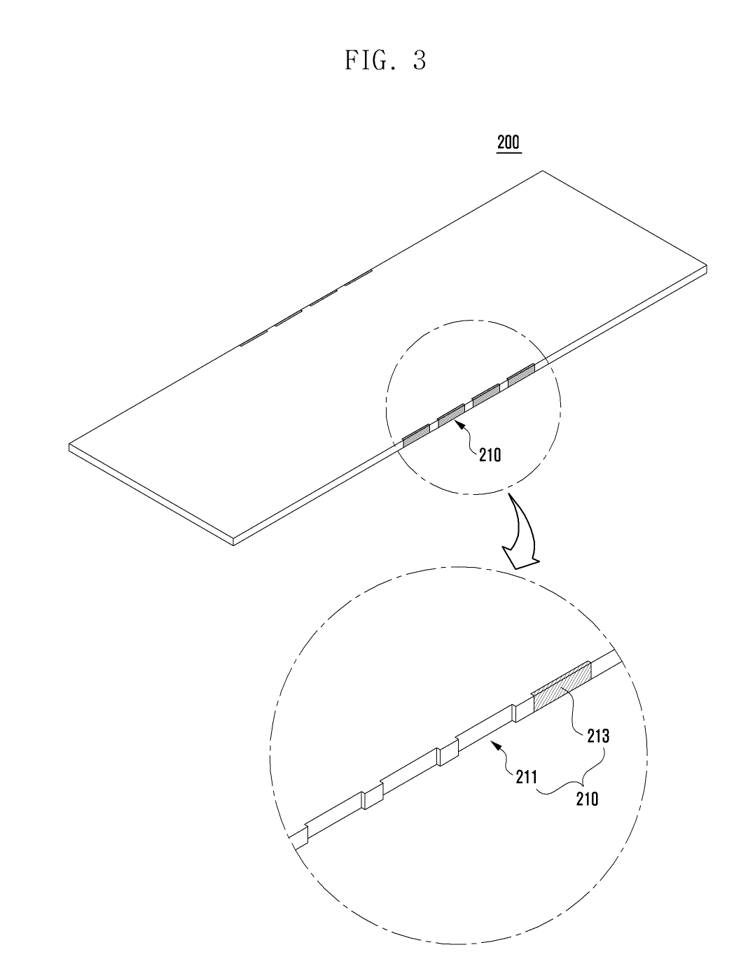

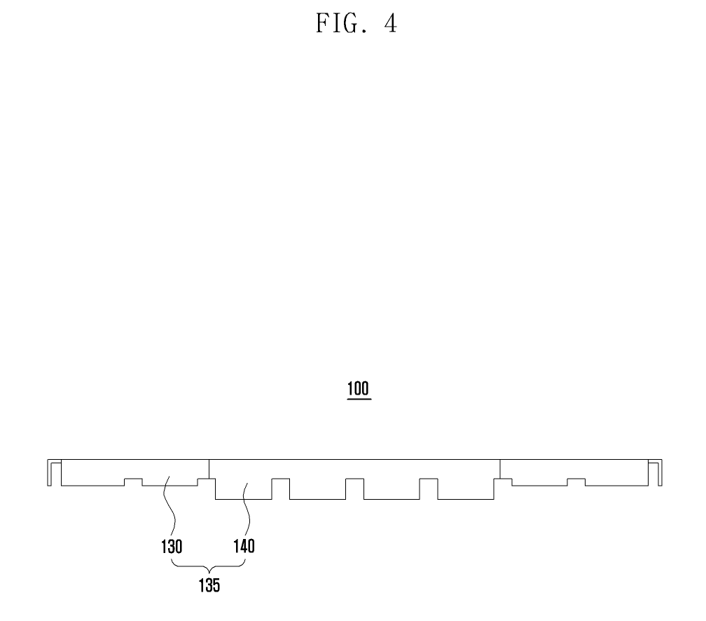

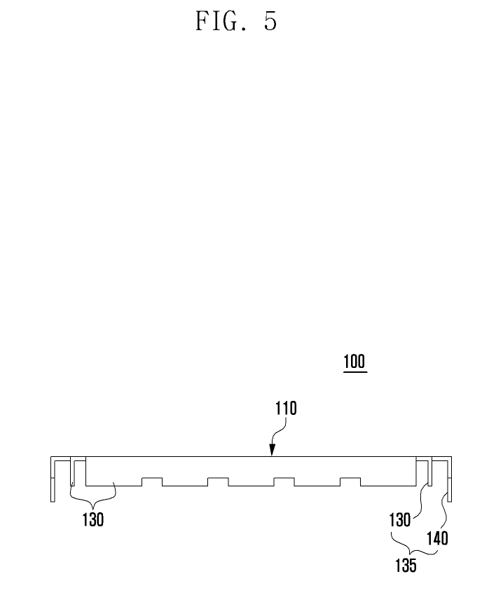

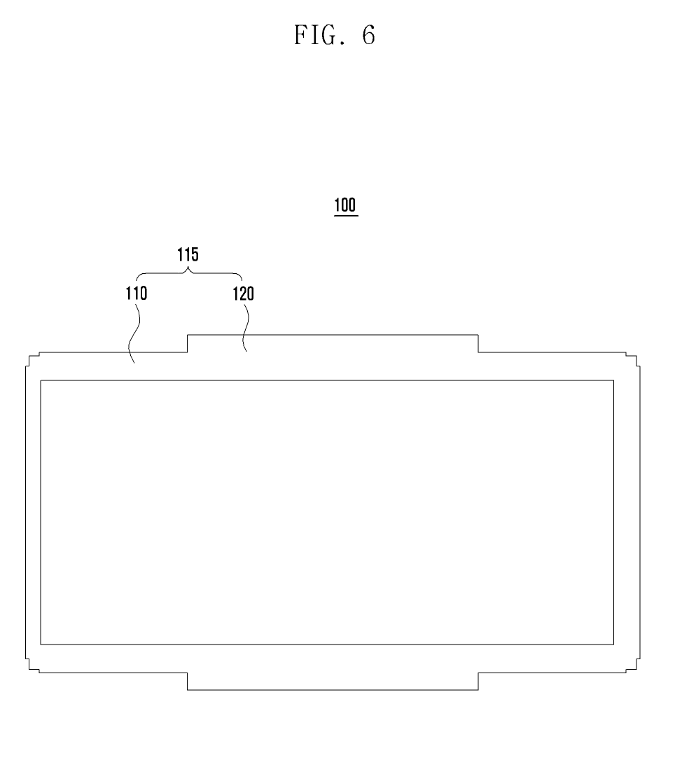

FIG. 1 illustrates a perspective view showing a shielding system according to a first exemplary embodiment of the present invention. FIG. 2 illustrates a perspective view showing a shield enclosure of the shielding system shown in FIG. 1 according to an exemplary embodiment of the present invention. FIG. 3 illustrates a perspective view showing a Printed Circuit Board (PCB) shown in FIG. 1 according to an exemplary embodiment of the present invention. FIG. 4 illustrates a side view showing the shield enclosure shown in FIG. 1 along a lengthwise direction according to an exemplary embodiment of the present invention. FIG. 5 illustrates a side view showing the shield enclosure shown in FIG. 1 along a widthwise direction according to an exemplary embodiment of the present invention. FIG. 6 illustrates a top view showing the shield enclosure shown in FIG. 1 according to an exemplary embodiment of the present invention.

Referring to FIGS. 1 to 6, the shielding system 10 includes a shield enclosure 100 and a PCB 200. The shielding system 10 is designed in such a way that the fixing members of the shield enclosure 100 are coupled to the sides of the PCB 200. The design can tightly fix the shield enclosure 100 to the PCB 200 so that it can enclose the components thereon, without requiring additional space from the PCB 200 in order to fix the shield enclosure 100 thereto. Therefore, the design allows the shield enclosure 100 to address the creation of noise from the components on the PCB 200 and also allows the shield enclosure 100 to provide stiffness to the PCB 200, thereby preventing the components on the PCB 200 from being damaged by an external impact.

Referring to FIGS. 1 and 2, the shield enclosure 100 is designed in such a way that a contact lead 135 contacts at least a part of a side of the PCB 200 and a cover 115 encloses components on the PCB 200.

The cover 115 is shaped to enclose one or more end sides of the components on the PCB 200 and is made of a material for shielding noise, such as a conductive material, etc. For example, the cover 115 may be shaped as a band with a certain width. The cover 115 includes a curb 110 shaped as a rectangular band according to the shape of the PCB 200 and an extension area 120 extended from at least one side of the curb 110. Although the illustrated exemplary embodiment is implemented in such a way that the cover 115 is formed to be empty in the center portion, it should be understood that the invention is not limited thereto. For example, the cover 115 may be shaped as a continuous plate having no hole in the center portion, as a discontinuous plate having a plurality of holes, slots, or similar openings formed therein, and the like. As shown in FIG. 2, the cover 115 is implemented in such a way that a fundamental frame is formed as a band with a certain width along the edge and an extension frame is coupled to the fundamental frame to enclose the components in the PCB 200. The extension frame mitigates noise from components in the PCB 200 and provides stiffness to the PCB 200. It is preferable that the fundamental frame and the extension frame are made of a conductive material, e.g., a metal.

The contact lead 135 is formed in such a way that it is extended from the side or edge of the cover 115 toward the PCB 200. The contact lead 135 includes a fixing lead 140 for contacting the side of the PCB 200 to fix the shield enclosure 100 thereto, and a supporting lead 130 contacting a front side of the PCB 200 to support the shield enclosure 100 thereabove.

The supporting lead 130 includes one or more walls extended from the cover 115. In an exemplary implementation, the supporting lead 130 may include one or more walls extended perpendicular to the cover 115. The supporting lead 130 supports the shield enclosure 100 in such a way that the ends contact the front side of the PCB 200. To this end, the PCB 200 may include grooves on the front side to receive the ends of the supporting lead 130, which will be described in greater detail later, referring to the accompanying drawings.

The fixing lead 140 extends from the edge of the cover 115 toward the PCB 200 to have a length so that the end portion can contact the side of the PCB 200. That is, the fixing lead 140 extends from the edge of the extension area 120 of the cover 115 toward the PCB 200 so that it can contact the side of the PCB 200 when the contact lead 135 is placed on the front side of the PCB 200. To this end, as shown in FIG. 2, the extension area 120 of the cover 115 has a greater width than the other part of the cover 115. The fixing lead 140 has a length, extending from the edge of the extension area 120 toward the PCB 200, so that the end portion can contact the side of the PCB 200. The fixing lead 140 has a greater length than the supporting lead 130.

The extension area 120 extends from the edge of the curb 110 toward the outside (i.e., an outer edge of the PCB) so that the fixing lead 140 extending toward the PCB 200 from the edge of the extension area 120 can contact the side of the PCB 200. Therefore, the width of the extension area 120 is the summation of the distance from a point where the supporting lead 130 is placed on the PCB 200 to the edge of the PCB 200 and the thickness of the fixing lead 140. As shown in FIG. 2, the extension areas 120 are formed at both lengthwise sides of the cover 115 respectively. Therefore, the fixing lead 140 is also formed at both lengthwise sides of the cover 115 respectively.

Although the illustrated exemplary embodiment is implemented in such a way that the fixing leads 140 are formed at both lengthwise sides of the cover 115 respectively, it should be understood that the invention is not limited thereto. That is, the fixing lead 140 and the extension area 120 may be formed on one or more sides of the cover 115 shaped as a band, so that the fixing lead 140 can contact corresponding sides of the PCB 200. For example, if the PCB 200 is shaped as a rectangle, the fixing lead 140 may be formed in such a way that the number and the width are set by at least one of the four sides of the PCB 200 that the corresponding fixing leads will contact. In that case, the number of extension areas 120 is set according to the number of fixing leads 140. In an exemplary embodiment of the present invention, the fixing leads 140 are formed at both lengthwise sides of the cover 115, and the supporting leads 130 are formed in the direction of the cover 115.

Referring to FIG. 3, the PCB 200 includes a number of hardware components for the mobile device and wires for transferring signals therebetween (not shown). The PCB 200 may also be implemented with a substrate onto which one or more copper sheets are laminated, forming multi-layers for space efficiency (not shown). The PCB 200 may include a contact area 210 for contacting the fixing lead 140 of the shield enclosure 100 on one or more sides. The contact area 210 is designed in such a way that a lead placement groove 211 is lower by a certain distance from the level of a side surface. Furthermore, a soldering material 213 may be filled into the lead placement groove 211. The number and the shape of the lead placement groove 211 correspond to those of the fixing lead 140. For example, as shown in FIGS. 1 to 3, if the fixing lead 140 is formed with four sidewalls perpendicularly extended from the edge of the extension area 120 of the cover 115, the PCB 200 may form four lead placement grooves 211 at the corresponding locations on the side. Each of the four lead placement grooves 211 may also be filled with soldering material 213. The four side walls of the fixing lead 140 of the shield enclosure 100 are arranged corresponding to the lead placement grooves 211. The four side walls of the fixing lead 140 of the shield enclosure 100 may then be coupled to the soldering materials 213 therein via a reflow process. In order to place the soldering material 213 into the lead placement groove 211, a pad on which a soldering material is deposited may be applied to the lead placement groove 211. Of course, this is merely an example and the soldering material 213 may be placed into the groove 211 using any of a plurality of methods.

As described above, the shield enclosure 100 is coupled to the PCB 200 in such a way that the fixing lead 140 contacts and is fixed to the side of the PCB 200. In this manner, the PCB 200 does not require a fixing space to adhere the shield enclosure 100 thereto, thus enabling the PCB 200 to be made smaller. Moreover, if hardware components need to be arranged in the front space of the PCB 200, the exemplary shielding system 10 can provide enough space to stably arrange them. In addition, since the fixing lead 140 of the shield enclosure 100 is tightly fixed to the soldering material 213 of the PCB 200 via a soldering process, the shield enclosure 100 can be permanently coupled to the PCB 200 which provides stiffness to the PCB 200. Therefore, the exemplary shielding system 10 can provide reliability to the hardware components in the PCB 200.

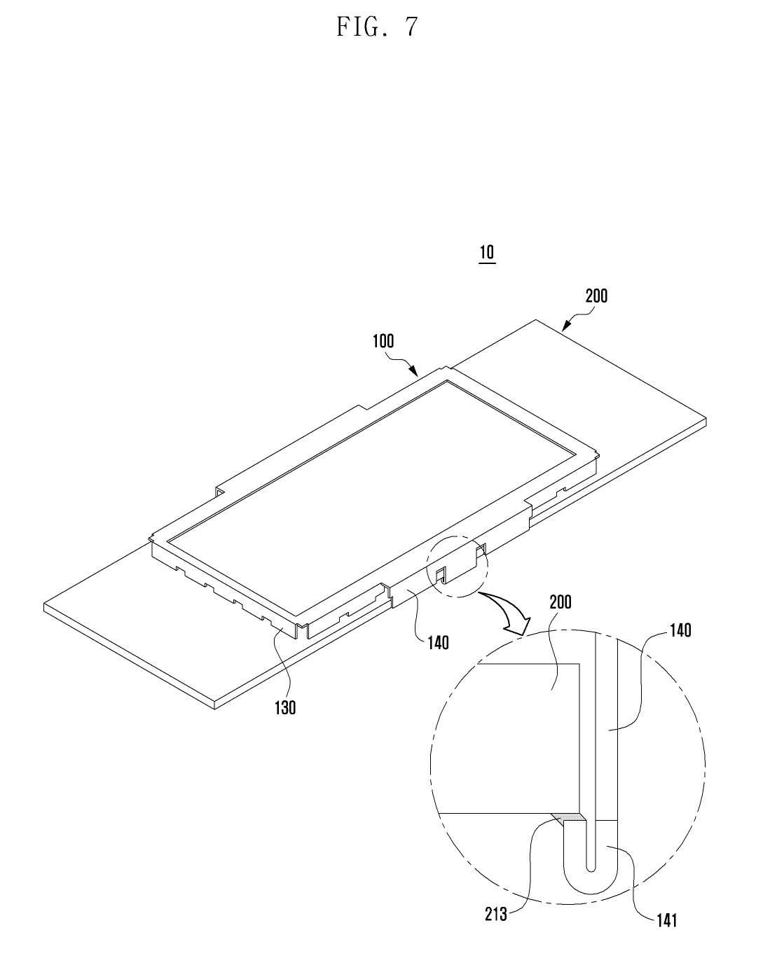

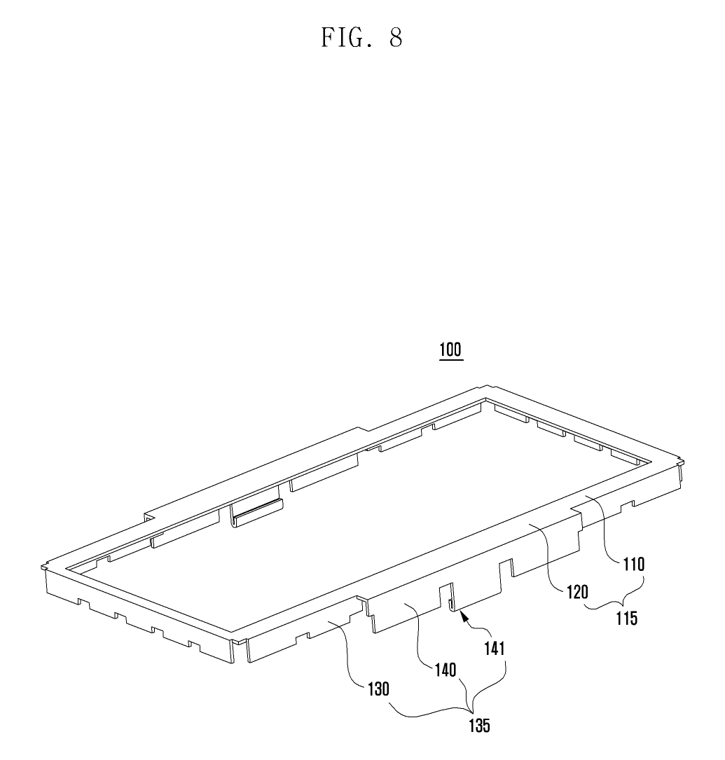

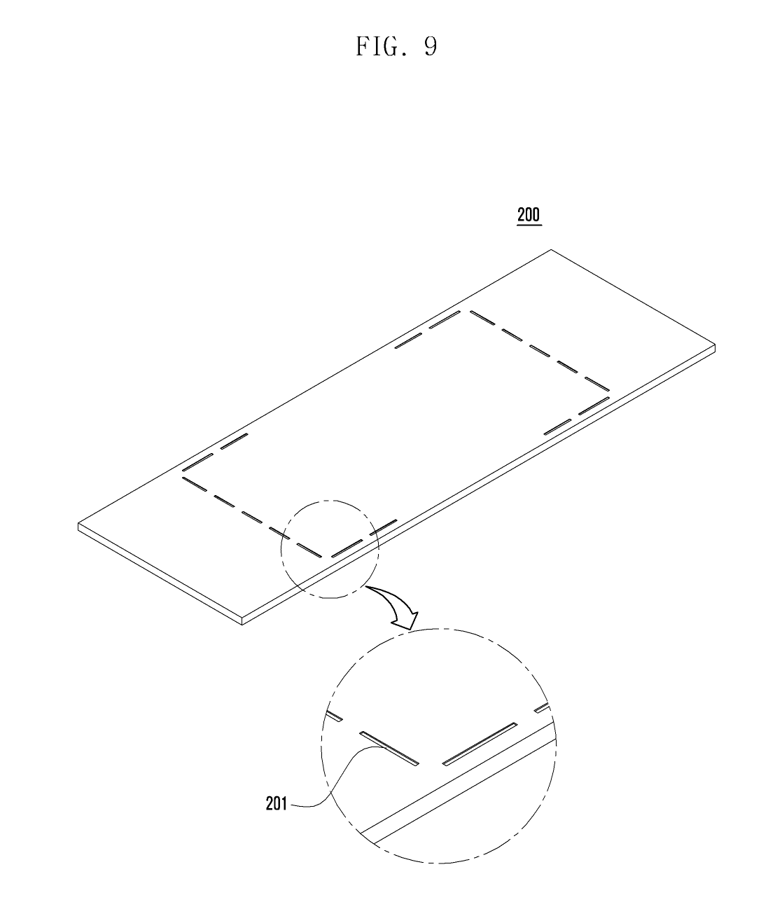

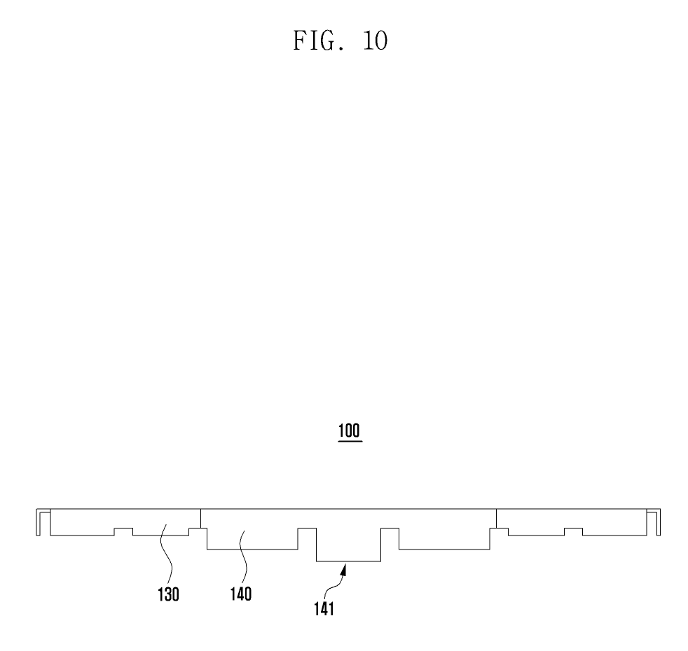

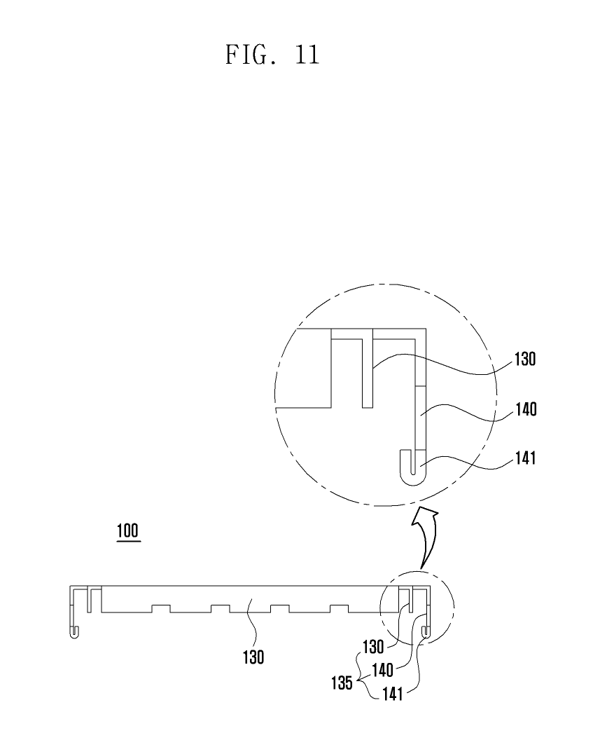

FIG. 7 illustrates a perspective view showing a shielding system according to a second exemplary embodiment of the present invention. FIG. 8 illustrates a perspective view showing a shield enclosure of the shielding system shown in FIG. 7 according to an exemplary embodiment of the present invention. FIG. 9 illustrates a perspective view showing a PCB shown in FIG. 7 according to an exemplary embodiment of the present invention. FIG. 10 illustrates a side view showing the shield enclosure shown in FIG. 7 along a lengthwise direction according to an exemplary embodiment of the present invention. FIG. 11 illustrates a side view showing the shield enclosure shown in FIG. 7 along a widthwise direction according to an exemplary embodiment of the present invention.

Referring to FIGS. 7 to 11, the shielding system 10 includes a shield enclosure 100 and a PCB 200.

The shield enclosure 100 includes a fixing lead 140 having a hook 141 formed at the end. The shield enclosure 100 is coupled to the PCB 200 in such a way that, when the fixing lead 140 contacts the side of the PCB 200, the hook 141 hooks the back side of the PCB 200. That is, the shield enclosure 100 can be fixed to the PCB 200 in such a way that the fixing lead 140 and the hook 141 are fixed to the sides and/or the back side of the PCB 200. As such, the shielding system 10 does not need an additional space in the front side of the PCB 200 for affixing the shield enclosure 100 and allows the shield enclosure 100 to enclose the components on the PCB 200. The design allows the shield enclosure 100 to mitigate noise from the components on the PCB 200. The design can also allow the shield enclosure 100 to provide stiffness to the PCB 200, thereby preventing the components on the PCB 200 from being damaged by an external impact. In an exemplary embodiment of the present invention, the hook 141 may be formed as an extension from the end of the fixing lead 140.

Referring to FIGS. 7 and 8, the shield enclosure 100 is designed in such a way that a contact lead 135 contacts the side (e.g., a lateral side) or/and the back side of the PCB 200 and a cover 115 encloses components on the PCB 200.

The cover 115 is shaped to enclose one or more end sides of the components on the PCB 200. For example, the cover 115 may be shaped as a plate with a certain area or as a band with a certain width. The cover 115 may be shaped according to the shape of the PCB 200. In an exemplary embodiment of the present invention as shown in FIG. 8, although the cover 115 is formed to be empty in the center portion, it should be understood that the invention is not limited thereto. For example, the cover 115 may be shaped as a continuous plate having no hole in the center portion, as a discontinuous plate having a plurality of holes, slots, or similar opening formed therein, and the like. As shown in FIG. 8, the cover 115 may be implemented in such a way that a fundamental frame is formed as a band with a certain width along the edge, and an extension frame is coupled to the fundamental frame to enclose the components in the PCB 200. The extension frame mitigates noise from components of the PCB 200 and provides stiffness to the PCB 200. To this end, the fundamental frame may include a structure to be coupled to the extension frame, and, likewise, the extension frame may also include the corresponding structure to be coupled to the fundamental frame.

The contact lead 135 includes side walls that extend from the side or edge of the cover 115 toward the PCB 200. That is, the contact lead 135 includes a fixing lead 140 for contacting the side (e.g., a lateral side) or the back side of the PCB 200 to fix the shield enclosure 100 thereto, and a supporting lead 130 contacting the front side of the PCB 200 to support the shield enclosure 100 thereabove.

The supporting lead 130 includes one or more walls extended from the cover 115. In an exemplary implementation, the supporting lead 130 may include one or more walls extended perpendicular to the cover 115. The supporting lead 130 supports the shield enclosure 100 in such a way that the ends contact the front side of the PCB 200. To this end, the PCB 200 may include grooves 201 on the front side to receive the ends of the supporting lead 130 as shown in FIG. 9.

Referring to FIG. 9, the grooves 201 are located on the front side of the PCB 200 at the corresponding locations where the supporting leads 130 are placed. Each of the grooves 201 may be formed having a depth that does not affect any circuit pattern formed in the substrate of the PCB 200, e.g., 0.1 mm. Although an exemplary embodiment of the present invention is implemented in such a way that the grooves 201 are located in the top and bottom on the front side of the PCB 200 so as to form a shape having angles ‘[’ and ‘],’ it should be understood that the invention is not limited thereto. The number of grooves 201 may be one or more. The grooves 201 are formed on the front side of the PCB 200 and receive the side walls of the supporting lead 130, extending from the edge of the cover 115 toward the PCB 200. Parts of the side walls of the supporting lead 130, received by the grooves 201, are longer than the remaining side walls that are not inserted into the grooves 201 by the depth of the groove 201. In an exemplary implementation, if the grooves 201 are designed to receive the ends of the entire side wall of the supporting lead 130, the supporting lead 130 may be formed so that the side walls have the same length.

The fixing lead 140 extends to have a length from the edge of the cover 115 toward the PCB 200 so that the end portion can contact the side and the back side of the PCB 200. That is, the fixing lead 140 extends from the edge of the extension area 120 of the cover 115 toward the PCB 200 so that it can contact the side or the back side of the PCB 200 when the contact lead 135 is placed on the front side of the PCB 200. To this end, the cover 115 shaped as a band may include one or more extension areas 120, each of which has a greater area than the other parts. The fixing lead 140 has a length in such a way that it extends from the edge of the extension area 120 toward the PCB 200, contacting the side of the PCB 200, to the back side of the PCB 200. Therefore, the fixing lead 140 has a greater length than the supporting lead 130, by the summation of the thickness of the PCB 200 and the length of the hook 141 protruded from the back side of the PCB 200 as shown in FIG. 11. As described above, the fixing lead 140 further forms the hook 141 at the end. As shown in FIG. 11, the hook 141 extends from the end of the fixing lead 140, passing by the level of the back side of the PCB 200, and is configured so that the end contacts the back side of the PCB 200. In an exemplary implementation, the end of the hook 141 can be soldered to the back side of the PCB 200, thereby fixing the shield enclosure 100 to the PCB 200. To this end, the PCB 200 may include a soldering pad 213 on the back side, thereby soldering the hook 141 thereto, for example via a reflow process.

The extension area 120 extends from the edge of the curb 110 toward the outside so that the fixing lead 140 extending toward the PCB 200 from the edge of the extension area 120 can contact the side of the PCB 200. Therefore, the width of the extension area 120 is the summation of the distance from a point where the supporting lead 130 is placed on the PCB 200 to the edge of the PCB 200 and the thickness of the fixing lead 140. The extension areas 120 are formed at both lengthwise sides of the cover 115 respectively. Therefore, the fixing leads 140 are also formed at both lengthwise sides of the cover 115 respectively.

Although the exemplary embodiment of the present invention is implemented in such a way that the fixing leads 140 with the hooks 141 are formed at both lengthwise sides of the cover 115 respectively, it should be understood that the invention is not limited thereto. That is, the fixing lead 140 and the extension area 120 may be formed in one or more sides of the cover 115 shaped as a band, so that the fixing lead 140 can contact corresponding sides and the back side of the PCB 200. For example, if the PCB 200 is shaped as a rectangle, the fixing lead 140 may be formed in such a way that the number and the width are set by at least one of the four sides of the PCB 200 and the back side of the PCB 200 that the corresponding fixing leads will contact. In that case, the number of extension area 120 is set according to the number of fixing leads 140. In an exemplary embodiment of the present invention, the fixing leads 140 are formed at both lengthwise sides of the cover 115, and the supporting leads 130 are formed in the widthwise direction of the cover 115.

The PCB 200 may be designed in substantially the same configuration as the first exemplary embodiment of the present invention shown in FIGS. 1 to 6, except that the PCB 200 of the second exemplary embodiment includes grooves 201 for receiving the supporting lead 130 on the front side. That is, the PCB 200 may be implemented with a substrate onto which one or more copper sheets are laminated, forming multi-layers for space efficiency. The PCB 200 may form a contact area 210 for contacting the fixing lead 140 of the shield enclosure 100 on one or more sides. The contact area 210 may be designed in such a way that a lead placement groove 211 is lower by a certain distance from the level of side surface. The number and the shape of the lead placement groove 211 correspond to those of the fixing lead 140. For example, if the fixing lead 140 is formed with four sidewalls perpendicularly extended from the edge of the extension area 120 of the cover 115, the PCB 200 may form four lead placement grooves 211 at the corresponding locations on the side. The hook 141 formed at the end of the fixing lead 140 contacts the back side of the PCB 200.

Although the second exemplary embodiment of the present invention is implemented in such a way that the lead placement groove 211 is formed on the side of the PCB 200, it should be understood that the invention is not limited thereto. That is, the second exemplary embodiment of the present invention may be modified in such a way that the PCB 200 does not form lead placement grooves 211 on the side and the hook 141 located at the end of the fixing lead 140 is soldered onto the back side of the PCB 200. To this end, the PCB 200 may include a pad with a soldering material 213 at the corresponding location on the back side where the hook 141 will be placed. In that case, when the shield enclosure 100 is placed to the PCB 200, the hook 141 can be soldered to the pad on the back side of the PCB 200, for example via a reflow process.

As described above, an exemplary shield enclosure 100 is coupled to the PCB 200 in such a way that the fixing lead 140 contacts the side of the PCB 200 and the hook 141 of the fixing lead 140 is fixed to the back side of the PCB 200. This can provide enough space to stably arrange hardware components on the PCB 200, without requiring the front space from the PCB 200. In addition, this can tightly fix the shield enclosure 100 to the PCB 200.

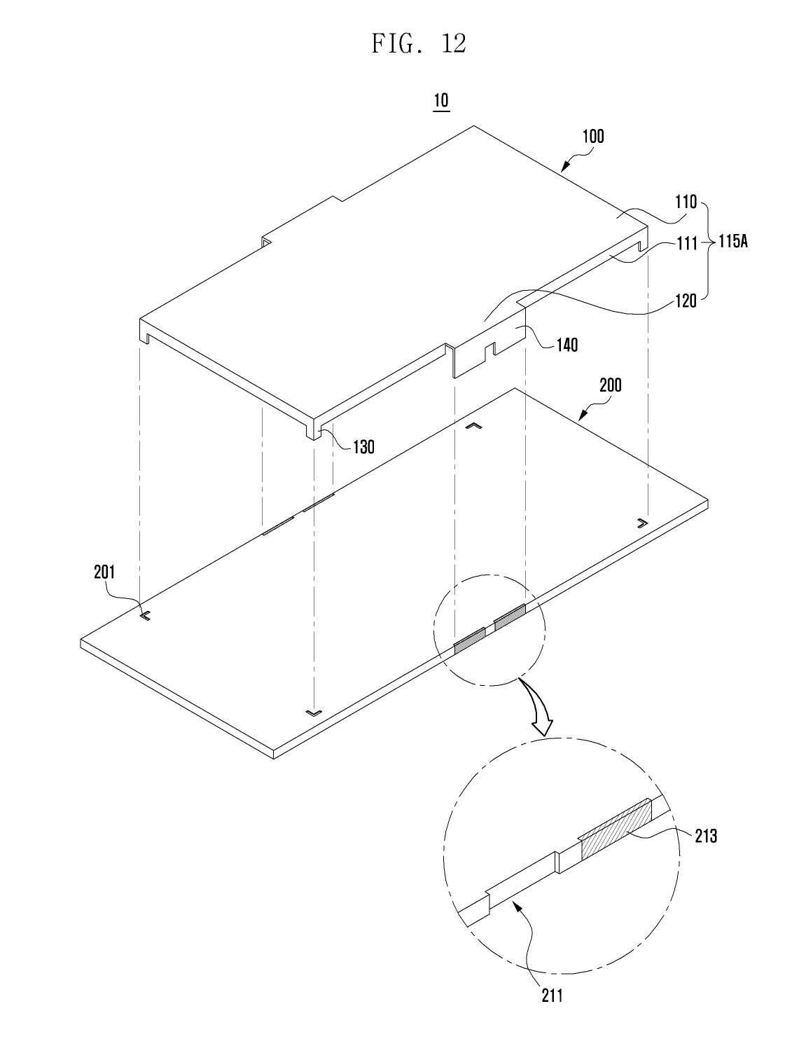

FIG. 12 illustrates a perspective view showing a shielding system according to a third exemplary embodiment of the present invention.

Referring to FIG. 12, a shielding system 10 is implemented in such a way that a cover 115A is formed in the front side of the shield enclosure 100, with a certain area, and in part of the side of the shield enclosure 100, supporting leads 130 are formed at the corners of the cover 115A, and a fixing lead 140 is formed in an extension area 120 of the cover 115A.

The cover 115A includes an enclosing part 110 with an area for covering the front side and side walls 111 each of which extends from the edge of the enclosing part 110 so that it has a certain area. In an exemplary implementation, the sidewalls 111 may include one or more walls extended perpendicular from the edge of the enclosing part 110. Part of a side wall 111 may be replaced with an extension area 120 extending toward the outside (e.g., an external edge) of the enclosing part 110, to have a certain area, and a fixing lead 140 extending from the edge of the extension area 120. In an exemplary implementation, the fixing lead 140 may extended perpendicularly from the edge of the extension area 120. The fixing lead 140 extends further than the side wall 111 toward the PCB 200 and contacts the side of the PCB 200.

The supporting leads 130 extend further than the side walls 111, however they extend less than the fixing leads 140. The supporting leads 130 are placed into grooves 201 formed on the PCB 200.

As described above, since the shield enclosure 100 is coupled to the PCB 200 in such a way that the cover 115A forms, at certain portions, e.g., corners, the supporting leads 130 to be placed into the grooves 201 of the PCB 200, and the fixing leads 140 of the extension areas 120 extending from the cover 115A contact the sides of the PCB 200 and are fixed thereto, for example via a soldering process and a reflow process, it can provide stiffness to the PCB 200. In addition, since the third exemplary embodiment of the shielding system 10 forms an optimum number of grooves 201 on the PCB 200, it can simplify the manufacturing process of the PCB 200.

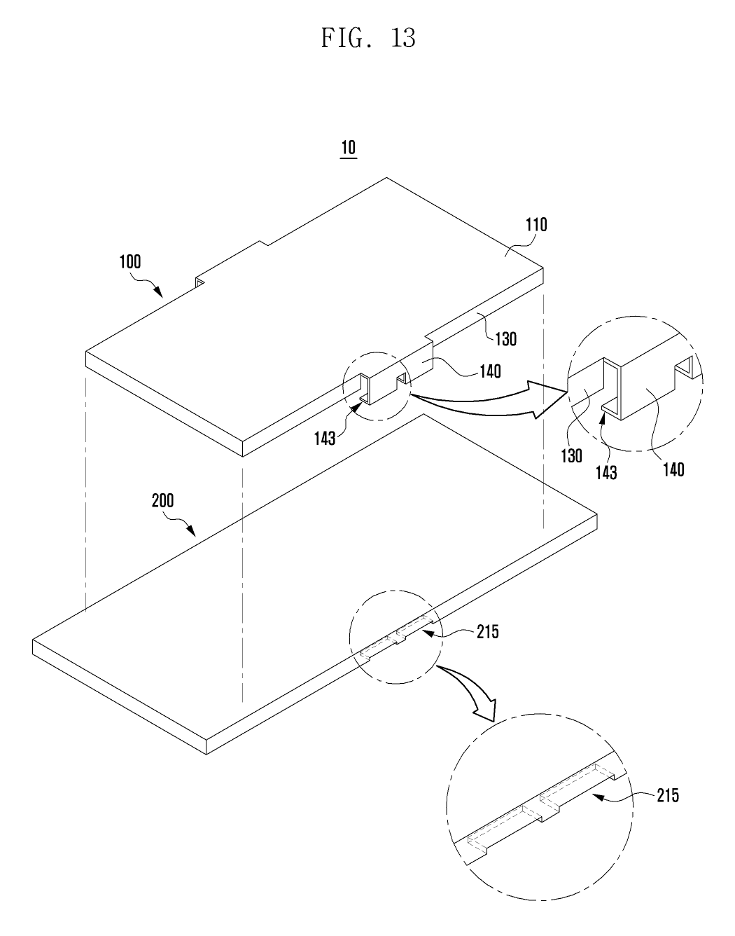

FIG. 13 illustrates a perspective view showing a shielding system according to a fourth exemplary embodiment of the present invention.

Referring to FIG. 13, a shield enclosure 100 of the fourth exemplary embodiment of the present invention is designed with similar components of those shown in FIGS. 7 to 11. However, the shield enclosure 100 of the fourth exemplary embodiment includes bent parts 143 instead of the hooks 141. The bent parts 143 extend from the end of the fixing lead 140 toward the PCB 200, so that they can contact the back side of the PCB 200. In an exemplary implementation, the bent parts 143 may extend perpendicularly from the end of the fixing lead 140. The PCB 200 includes locking grooves 215 to receive the bent parts 143 at the corresponding locations on the back side. The locking grooves 215 may guide the bent parts 143 for ease of placement of the bent parts 143. In an exemplary implementation, the locking grooves 215 may include soldering materials. In that case, the bent parts 143 can be tightly fixed to the locking grooves 215 via the soldering materials, for example by a reflow process. The bent parts 143 may also be formed in such way that the fixing leads 140 are extended.

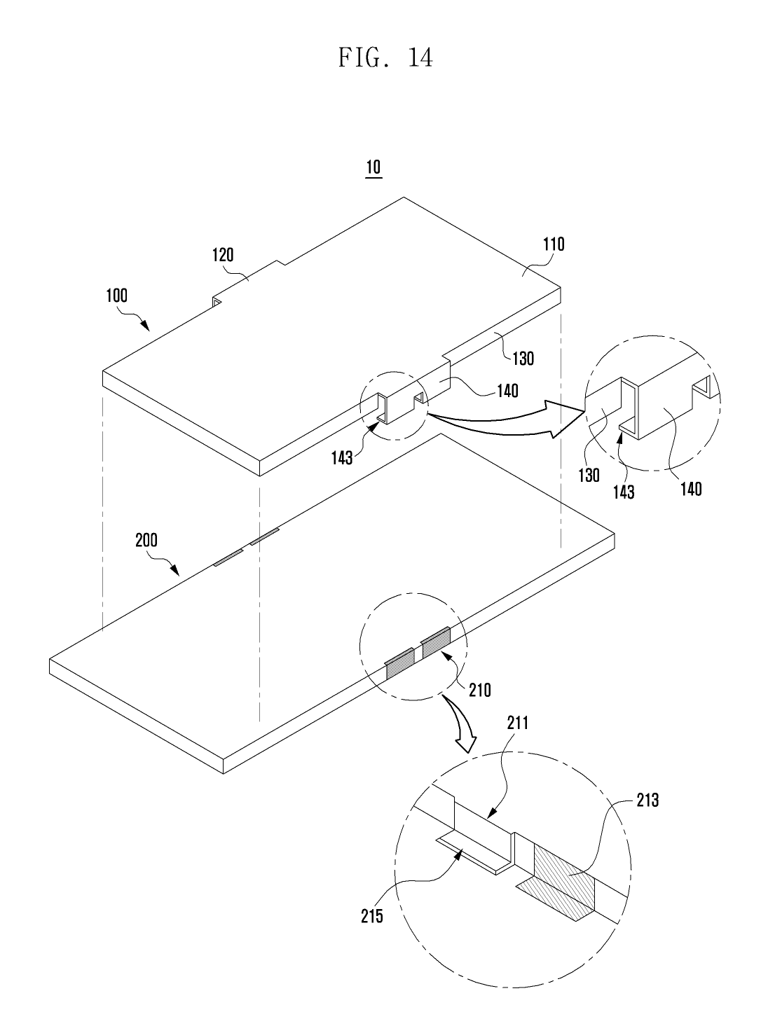

FIG. 14 illustrates a perspective view showing a modification of the shielding system shown in FIG. 13 according to an exemplary embodiment of the present invention.

Referring to FIG. 14, the fourth exemplary embodiment of shielding system 10 may be modified in such a way that the PCB 200 forms a lead placement groove 211 on the side and a locking groove 215 on the back side, where the lead placement groove 211 and the locking grooves 215 are placed side by side. In addition, the extension area 120 may include a fixing lead 140 and a bent part 143, where the fixing lead 140 is fixed to the lead placement groove 211 and the bent part 143 is fixedly received by the locking groove 215. The lead placement groove 211 and the locking groove 215 can be coupled to the fixing lead 140 and the bent pat 143, for example via soldering material and reflow processes, respectively. The PCB 200 may include a soldering pad on the surface in order to protect the grooves formed thereon and to locate the soldering material therein. The soldering pad may be implemented with a metal plate shaped as a thin film.

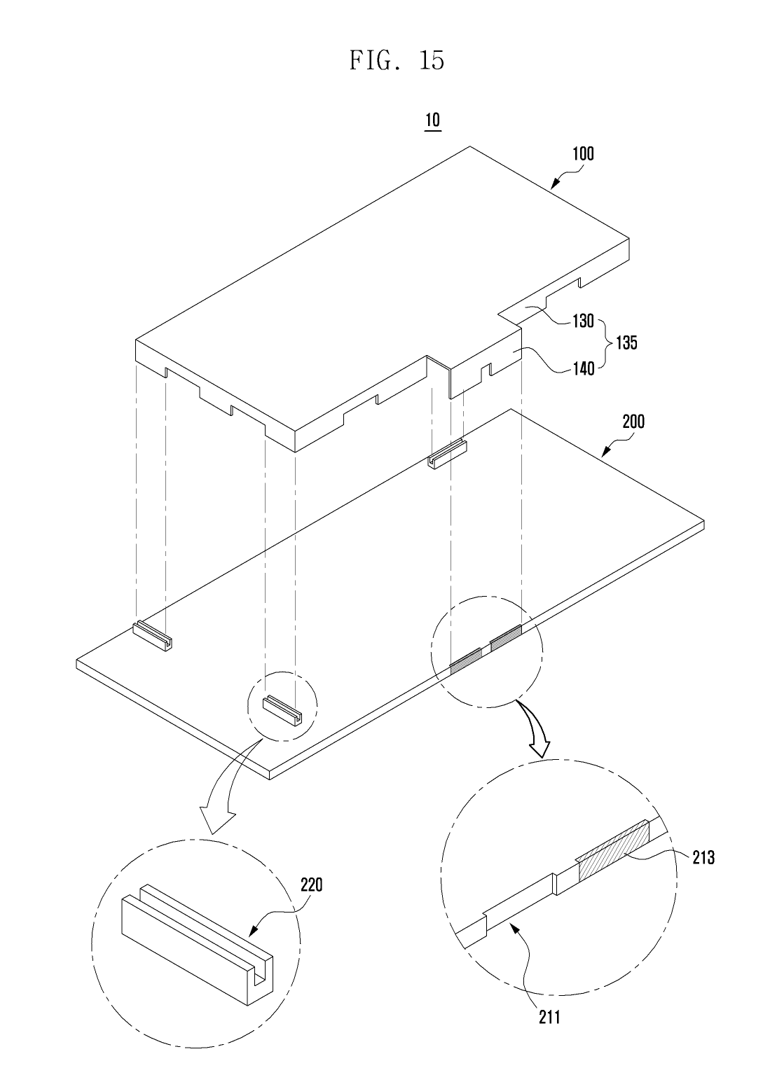

FIG. 15 illustrates a perspective view showing a shielding system according to a fifth exemplary embodiment of the present invention.

Referring to FIG. 15, the shielding system 10 is designed in such a way that the shield enclosure 100 includes a contact lead 135. The contact lead 135 is coupled to PCB 200 in such a way that one side is inserted to a slot unit 220 located on the PCB 200, and the other side is fixed to the lead placement groove 211 located on the side (e.g., a lateral side) and/or the back side of the PCB 200. The slot unit 220 may be fixed onto the front side of the PCB 200, for example via a soldering material and a reflow process. The contact lead 135 may be fitted into the slot unit 220 and separated therefrom by applying an external force to the contact lead 135. The shield enclosure 100 of the fifth exemplary embodiment of the present invention may be applied to PCBs having restricted use of their sides, so that it can still provide stiffness to the PCBs.

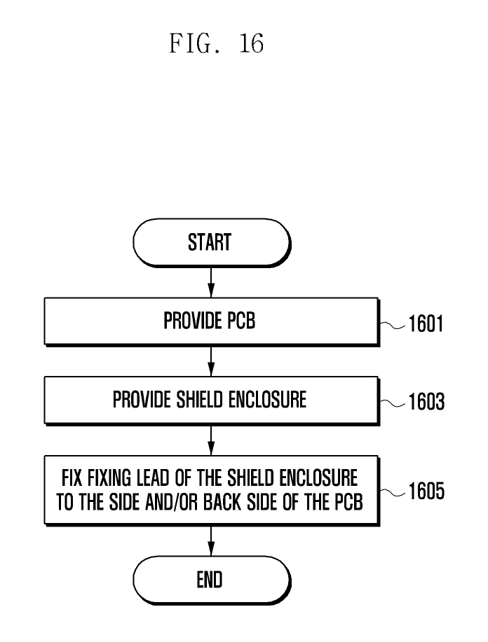

FIG. 16 illustrates a flowchart that describes a method for assembling the shielding system 10 according to an exemplary embodiment of the present invention.

Referring to FIG. 16, a PCB 200 is provided in step 1601. A shield enclosure 100 with a cover, located above the PCB 200, and a fixing lead extending from the cover, is provided in step 1603. The fixing lead of the shield enclosure 100 is fixed to the side and/or the back side of the PCB 200 in step 1605. As described above, the exemplary assembly method can easily couple the shield enclosure 100 to the PCB 200, so that the shield enclosure 100 can provide stiffness to the PCB 200.

The fixation of the shield enclosure 100 to the side and/or the back side of the PCB may include forming a lead placement groove, formed on the side of the PCB at a location corresponding to the fixing lead, and/or a pent part formed at the back side of the PCB, placing a pad with a soldering material in the lead placement groove and/or the bent part, arranging the shield enclosure with the fixing lead to the lead placement groove and/or the bent part, and fixing the fixing lead to the lead placement groove and/or the bent part via a reflow process.

The shield enclosure may further include a fixing lead, a hook, or a bent part. The fixing lead extends from the cover and may perpendicularly extend from the cover. The hook is formed at the end of the fixing lead in such a way that it is bent toward the back side of the PCB and contacts the back side of the PCB. The bent part is formed at the end of the fixing lead in such a way that it is bent toward the back side of the PCB, perpendicular to the fixing lead.

In an exemplary implementation, the method for assembling the shielding system may further include forming one or more grooves each of which has a certain depth and an area on the front side of the PCB, and placing supporting leads, extending parallel to the fixing lead and the cover of the shield enclosure 100, into the grooves. The exemplary method for assembling the shielding system may further include placing one or more slot units on the front side of the PCB, and fitting supporting leads, extending parallel to the fixing lead and the cover of the shield enclosure 100, into the slot units via an external force.

As described above, since the shielding system 10 is designed in such a way that the shield enclosure 100 forms one or more fixing leads 140 that are fixed to one or more sides of the PCB 200, it can tightly couple the shield enclosure 100 to the PCB 200 and thus provide reliability in operation. In addition, the PCB of the shielding system 10 can be designed to use a combination of part of the side and slot units or screws, considering the shape of the PCB or the space area of the PCB where electric components are mounted, thereby providing extension for coupling shield enclosures to PCBs.

As described above, the shielding system and the method for assembling the system, according to exemplary embodiments of the present invention, can tightly fix the shield enclosure to the PCB, providing a proper coupling space area where components will be installed, and can reduce the size of mobile devices. The shielding system and the method for assembling the system can retain the stiffness of a PCB via the shield enclosure.

The shielding system according to exemplary embodiments of the present invention can be applied to mobile devices. Here, the term mobile device includes any information communication devices, multimedia devices, and their applications, which are operated according to communication protocols corresponding to various types of communication systems. For example, the mobile device can be applied to mobile communication terminals, Portable Multimedia Players (PMPs), digital broadcast players, Personal Digital Assistants (PDAs), audio players (e.g., MP3 players), mobile game players, smartphones, laptop computers, hand-held PC, etc.

While the invention has been shown and described with reference to certain exemplary embodiments thereof, it will be understood by those skilled in the art that various changes in form and details may be made therein without departing from the spirit and scope of the invention as defined by appended claims and their equivalents.

What is claimed is:

1. A shielding system for a mobile device, the system comprising:
a Printed Circuit Board (PCB) with a first area and a thickness; and
a shield enclosure, spaced apart and above a front side of the PCB at a certain distance, for enclosing components on the PCB,
wherein parts of the shield enclosure are coupled to at least one of a lateral side and a back side of the PCB.

2. The system of claim 1, wherein the shield enclosure comprises:
a cover with a second area;
a supporting lead for contacting the front side of the PCB, wherein the supporting lead comprises side walls extending from an edge of the cover; and
a fixing lead, extending from the edge of the cover, for contacting and being fixed to at least one of the lateral side and the back side of the PCB.

3. The system of claim 2, wherein the fixing lead extends perpendicularly from the edge of the corner.

4. The system of claim 3, further comprising:
one or more grooves, formed on the front side of the PCB, for receiving the supporting lead.

5. The system of claim 3, further comprising:
one or more lead placement grooves, located on the lateral side of the PCB, for receiving the fixing lead.

6. The system of claim 5, further comprising:
a soldering pad, located in the lead placement groove, for coupling the fixing lead to the lead placement groove.

7. The system of claim 6, wherein a reflow process is used to couple the fixing lead to the lead placement groove using the soldering pad.

8. The system of claim 3, further comprising:
a hook located at the end of the fixing lead in such a way that it is bent toward the back side of the PCB; or
a bent part formed at the end of the fixing lead in such a way that it is bent toward the back side of the PCB, perpendicular to the fixing lead.

9. The system of claim 8, further comprising:
a soldering pad on the back side of the PCB, corresponding to an area where the hook approaches the back side of the PCB.

10. The system of claim 8, further comprising:
a locking groove, formed on at least one side of the back side of the PCB, for receiving the bent part.

11. The system of claim 10, further comprising:
a soldering pad, located in the locking groove, for coupling the bent part to the locking groove.

12. The system of claim 11, wherein a reflow process is used to couple the bent part to the locking groove using the soldering pad.

13. The system of claim 3, further comprising:
a slot unit, placed on the front side of the PCB, for receiving the supporting lead.

14. A method for assembling a shielding system, the method comprising:
providing a Printed Circuit Board (PCB);
providing a shield enclosure that comprises a cover, above the PCB, and a fixing lead extending from the cover; and
fixing the fixing lead of the shield enclosure to at least one of a lateral side and a back side of the PCB.

15. The method of claim 14, wherein the fixing of the fixing lead of the shield enclosure to the at least one of the lateral side and the back side of the PCB comprises:
forming at least one of a lead placement groove, formed on the lateral side of the PCB at a location corresponding to the fixing lead, and a bent part formed at the end of the fixing lead in such a way that it is bent toward the back side of the PCB;
placing a pad with a soldering material in at least one of the lead placement groove and a location on the back side of the PCB corresponding to the bent part;
arranging the shield enclosure with the fixing lead to at least one of the lead placement groove and the location on the back side of the PCB corresponding to the bent part; and
fixing the fixing lead to the at least one of the lead placement groove and the location on the back side of the PCB corresponding to the bent part.

16. The method of claim 15, wherein the fixing of the fixing lead comprises using a solder reflow process to couple the fixing lead to the at least one of the lead placement groove and the location on the back side of the PCB corresponding to the bent part.

17. The method of claim 14, wherein the providing of the shield enclosure comprises at least one of the following:
forming a fixing lead perpendicularly extending from the cover;
forming a hook at the end of the fixing lead in such a way that it is bent toward the back side of the PCB and contacts the back side of the PCB; and
forming a bent part at the end of the fixing lead in such a way that it is bent toward the back side of the PCB, perpendicular to the fixing lead.

18. The method of claim 14, further comprising:
forming one or more grooves each of which has a certain depth and an area on a front side of the PCB; and
placing supporting leads, extending parallel to the fixing lead and the cover of the shield enclosure, into the grooves.

19. The method of claim 14, further comprising:
placing one or more slot units on a front side of the PCB; and
fitting supporting leads, extending parallel to the fixing lead and the cover of the shield enclosure, into the slot units via an external force.
